(19) United States
(12) Patent Application Publication
(10) Pub. No.: US 2025/0218924 A1
(43) Pub. Date: Jul. 3, 2025

(54) ELECTROLESS NICKEL-ELECTROLESS PALLADIUM-IMMERSION GOLD (ENEPIG) AS A SURFACE FINISH FOR EMBEDDED DIE ATTACHMENTS

(71) Applicant: Intel Corporation, Santa Clara, CA (US)

(72) Inventors: Prithwish Chatterjee, Chandler, AZ (US); Shruti Sharma, Chandler, AZ (US); Numair Ahmed, Chandler, AZ (US); Yuxin Fang, Chandler, AZ (US); Wei-Lun Jen, Phoenix, AZ (US); Siddharth Alur Narasimha Krishna, Gilbert, AZ (US); Mollie A. Stewart, Lake Oswego, OR (US); Srinivas Venkata Ramanuja Pietambaram, Chandler, AZ (US); Suresh T. Narute, Chandler, AZ (US)

(21) Appl. No.: 18/400,878

(22) Filed: Dec. 29, 2023

(51) Int. Cl. H01L 23/498; H01L 21/48; H01L 23/00; H01L 23/13; H01L 23/538

(52) U.S. Cl. CPC H01L 23/49866; H01L 21/4846; H01L 23/13; H01L 23/49833; H01L 23/5385; H01L 24/16; H01L 24/81; H01L 24/13; H01L 2224/13111; H01L 2224/13139; H01L 2224/13147; H01L 2224/16227; H01L 2224/16503; H01L 2224/81444; H01L 2924/014

(57) ABSTRACT

In embodiments herein, a surface finish (SF) is formed on conductive contacts of a package substrate for connection to an embedded interconnect bridge circuitry die. In some embodiments, the SF may be electroless nickel-electroless palladium-immersion gold (ENEPIG). In other embodiments, the SF may be immersion gold-electroless palladium-immersion gold (IGEPIG). In other embodiments, the SF may include a layer of electrolytic palladium-gold on a layer of indium or on a layer of cobalt-iron.

### BACKGROUND

Circuit components, e.g., power delivery components such as inductors and capacitors, may be embedded within a core of a package substrate for an integrated circuit package. However, embedding components has proven to be difficult due to various factors, such as thickness mismatches between the core and the component, which can lead to tilting or shifting of the component within the cavity.

### BRIEF DESCRIPTION OF THE DRAWINGS

FIG. 1 illustrates an example multi-die integrated circuit package with an embedded interconnect bridge circuitry component.

FIGS. 2A-2E illustrate a first example process of embedding an interconnect bridge circuitry die in a package substrate in accordance with embodiments of the present disclosure.

FIG. 3 illustrates an example material stack that may be deposited as a surface finish in the process of FIGS. 2A-2E in accordance with embodiments of the present disclosure.

FIG. 4 illustrates an example material stack that may be deposited as a surface finish in the process of FIGS. 2A-2E in accordance with embodiments of the present disclosure.

FIG. 5 illustrates an example material stack that may be in an integrated circuit package after being manufactured according to the process of FIGS. 2A-2E with the material stack of FIG. 3.

FIG. 6 illustrates another example material stack that may be in an integrated circuit package after being manufactured according to the process of FIGS. 2A-2E with the material stack of FIG. 3.

FIG. 7 illustrates an example material stack that may be in an integrated circuit package after being manufactured according to the process of FIGS. 2A-2E with the material stack of FIG. 4.

FIGS. 8A-8E illustrate a second example process of embedding an interconnect bridge circuitry die in a package substrate in accordance with embodiments of the present disclosure.

FIG. 9 illustrates an example material stack that may be deposited as a surface finish in the process of FIGS. 8A-8E in accordance with embodiments of the present disclosure.

FIG. 10 illustrates another example material stack that may be deposited in the process of FIGS. 8A-8E in accordance with embodiments of the present disclosure.

FIG. 11 illustrates an example material stack that may be in an integrated circuit package after being manufactured according to the process of FIGS. 8A-8E with the material stack of FIG. 9.

FIG. 12 illustrates an example material stack that may be in an integrated circuit package after being manufactured according to the process of FIGS. 8A-8E with the material stack of FIG. 10.

FIGS. 13A-13B illustrate example systems that may incorporate the architectures described herein.

FIG. 14 is a top view of a wafer and dies that may be included in a microelectronic assembly, in accordance with any of the embodiments disclosed herein.

FIG. 15 is a cross-sectional side view of an integrated circuit device that may be included in a microelectronic assembly, in accordance with any of the embodiments disclosed herein.

FIG. 16 is a block diagram of an example electrical device that may include a microelectronic assembly, in accordance with any of the embodiments disclosed herein.

### DETAILED DESCRIPTION

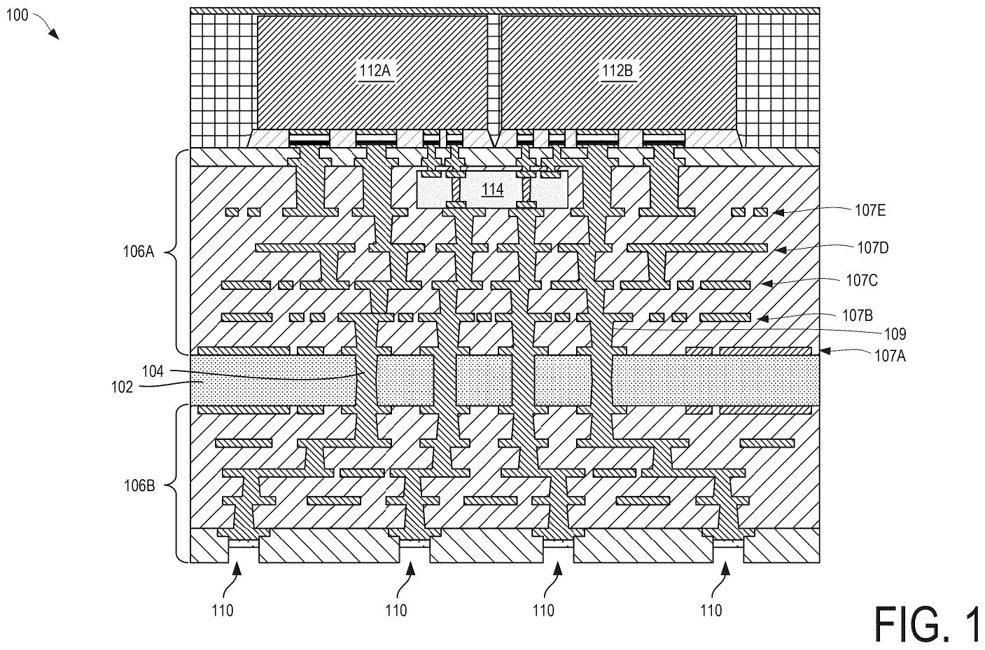

Embodiments of the present disclosure relate to processes for embedding interconnect bridge circuitry dies in multi-die integrated circuit packages. More specifically, embodiments herein are directed to techniques for forming surface finishes (SFs) on conductive contacts of a package substrate, e.g., on bumps within a cavity of a package substrate (cavity side bumps or CSBs) that are to connect to a die embedded within the cavity. As used herein, cavity side bumps (CSBs) may refer to conductive contacts of a package substrate that connect to a bottom side of an interconnect bridge circuitry die embedded within the package substrate, e.g., as shown in FIG. 1. Due to increasing power delivery demands, integrated circuit package substrates have increasingly implemented embedded interconnect bridge circuitry dies that include through silicon vias (TSVs), which have conductive contacts on a top side and bottom side to allow for power delivery through the embedded interconnect bridge circuitry die to the integrated circuit dies coupled to the interconnect bridge circuitry die.

Typically, surface finishes may be formed using electroless nickel electroless palladium immersion gold (ENEPIG), i.e., where nickel is deposited via electroless plating, palladium is also deposited via electroless plating, and gold is deposited via immersion plating. In fact, ENEPIG has been used for multiple generations of integrated circuit package designs due to its good solder joint reliability (SJR) and electromigration performance. A surface finish (SF) may refer to one or more material layers (e.g., metal layers) formed at a solderable area on a circuit board, e.g., formed on conductive contacts of an integrated circuit package substrate. Some recent process flows have utilized an electrolytic (e-lytic or elytic) SF (i.e., the SF is deposited using electrolytic plating) that includes palladium and gold formed on cavity side bumps (CSBs) of a package substrate to connect to an embedded interconnect bridge circuitry die with TSVs. However, omitting nickel in the SF for CSBs can lead to SJR concerns, e.g., due to potentially having copper diffused into the palladium and gold layers to form uncontrolled copper-tin inter-metallic compounds (IMCs). Additionally, to ensure minimal oxidation of the copper CSBs, higher thicknesses of palladium and gold may be needed (since there is no layer of nickel), which could lead to formation of PdSn₄ and AuSn₄ alloys that are highly brittle and cause failures (this may be referred to as palladium/gold embrittlement). Gold-only plating can lead to voids (due to the electrochemistry of copper vs gold), in addition to bath life concerns of gold bath from copper contamination. Similar concerns and effects have been raised and observed for PdAu plating as well.

Embodiments herein implement techniques that can address or avoid such issues. For example, some embodiments may implement a process flow that allows for the use of ENEPIG as a SF in an integrated circuit package substrate, which may avoid potential SJR concerns through the introduction of Ni, as well as concerns related to maximum current (Imax) limits due to the use of an ENEPIG SF. Some embodiments may implement a process flow that allows for the use of an ENEPIG SF with a relatively thin nickel layer. Other embodiments, however, may implement a process flow that allows for the use of immersion gold electroless palladium immersion gold (IGEPIG) as a SF in an integrated circuit package substrate. Other embodiments may implement a process flow that utilizes a SF that includes a layer of indium in addition to layers of palladium and gold, while other embodiments may implement a process flow that utilizes a SF that includes a layer of cobalt-iron in addition to layers of palladium and gold.

Accordingly, embodiments of the present disclosure may provide one or more advantages over existing process flows. As one example, the process flows described herein (e.g., those related to electroless plating) may offer cost reduction opportunities due to the reduction of an additional lithography step related to the deposition of e-lytic SF materials. Moreover, some embodiments may be able to use existing process flow steps and tools, allowing for faster and cheaper implementation of such processes. Further, embodiments herein may provide better SJR and Imax performance due to reductions in the formation of brittle IMCs and reduced IMC formation kinetics. Additionally, embodiments that involve electroless plating herein may have improved wettability due to full coverage of the SF (including the side of the pads), leading to low copper oxidation and uniform tin wicking. Other advantages may be apparent to those of skill in the art, and additional advantages are described below with respect to certain embodiments.

It will be understood that in the examples shown and described further below, the figures may not be drawn to scale and may not include all possible layers and/or circuit components. In addition, it will be understood that although certain figures illustrate designs with boundaries between surfaces being orthogonal (e.g., perpendicular), embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

FIG. 1 illustrates an example multi-die integrated circuit package 100 with an embedded interconnect bridge circuitry component 114. The package 100 includes a core layer 102 and vias 104 through the core layer 102. Buildup layers 106 are formed on the top and bottom sides of the core layer 102, with buildup layers 106A on the top side of the core layer 102 and the buildup layers 106B on bottom side of the core layer 102. The buildup layers 106 include metal traces in metallization layers (e.g., 107A-E) and pillars (e.g., 109) between the metallization layers as shown to electrically couple components on the top of the package 100 with the pads 110 at the bottom of the package. For example, the layers 106 may provide connections between the integrated circuit (IC) dies 112 coupled to the top side of the package to a circuit board (e.g., a motherboard, main board, etc.) via the pads 110 at the bottom of the package. The package 100 also includes an interconnect bridge circuitry component 114 located in the buildup layers 106A that electrically couples the first IC die 112A with the second IC die 112B. The interconnect bridge circuitry component 114 may include passive and/or active components to interconnect the IC dies 112. As shown, the interconnect bridge circuitry component 114 includes through silicon vias to connect a top side of the component 114 with a bottom side. The interconnect bridge circuitry component 114 may be an Intel® embedded multi-die interconnect bridge with through silicon vias (EMIB-T) in certain embodiments.

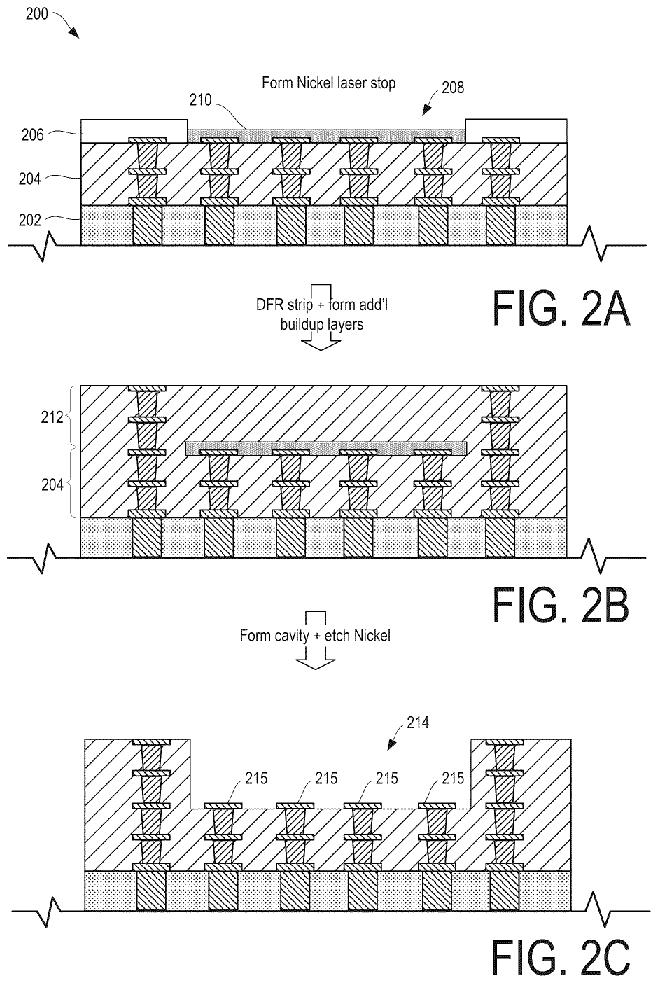

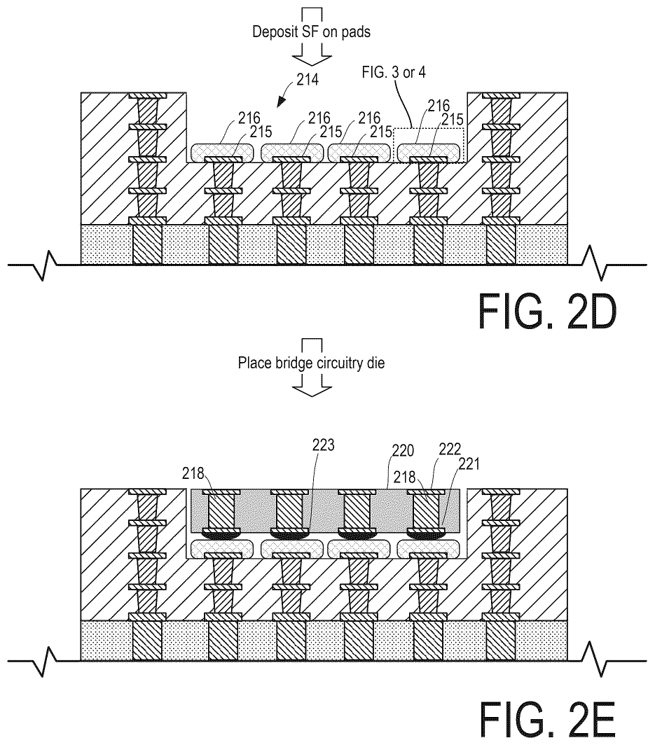

FIGS. 2A-2E illustrate a first example process 200 of embedding an interconnect bridge circuitry die in a package substrate in accordance with embodiments of the present disclosure. The process may include additional, fewer, or different operations than those shown or described below. In some embodiments, one or more of the operations shown include multiple operations, sub-operations, etc.

Referring to FIG. 2A, the example process 200 includes the formation of dielectric buildup layers 204 on a core layer 202 as shown. The buildup layers include metallization layers and pillars similar to the example described above with respect to FIG. 1. Then, a laser stop layer 210 is formed within an opening 208 in a photoresist layer 206 (e.g., a dry film resist (DFR) layer) on the buildup layers 204. The laser stop layer 210 may include nickel or any other suitable material. Then, as shown in FIG. 2B, the photoresist layer 206 is removed and additional buildup layers 212 are formed on the buildup layers 204 as shown, including forming the dielectric buildup layer in the area above the laser stop layer 210. Then, as shown in FIG. 2C, a cavity 214 is formed (e.g., via laser drilling) in the area above the laser stop layer 210 until the laser stop layer 210 is exposed, and then the laser stop layer 210 can be removed (e.g., etched) to expose a set of conductive pads 215 in a metallization layer.

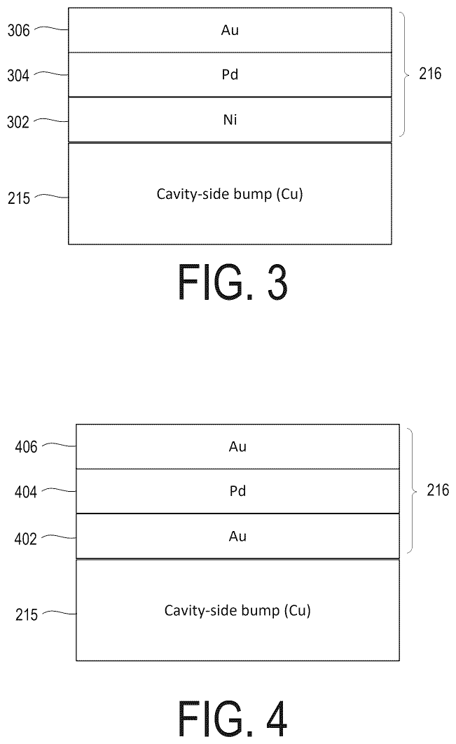

Referring then to FIG. 2D, a surface finish (SF) 216 is then formed (e.g., deposited) on the pads 215. In some embodiments, the SF 216 may include the material stack shown in FIG. 3, which may be an electroless nickel-electroless palladium-immersion gold (ENEPIG) SF. That is, the SF 216 may include a layer 302 comprising nickel on the copper pad 215 in the cavity 214 of the package substrate, a layer 304 comprising palladium on the layer 302, and a layer 306 comprising gold on the layer 304. The layer 302 may be formed via electroless plating, the layer 304 may be formed via electroless plating, and the layer 306 may be formed by immersion plating, as the ENEPIG name implies.

In some embodiments, the layer 302 may be between 5-10 um (e.g., 7 um) thick, the layer 304 may be between 0.01-0.10 um (e.g., 0.04 um) thick, and the layer 306 may be between 0.01-0.10 um (e.g., 0.06 um) thick. Some existing dies 220 have copper pads 221 or 222 that are approximately 15 μm thick; however, because the layer 302 in the SF may be relatively thick, e.g., 7 μm thick, embodiments herein may instead implement a die 220 having pads 221 or 222 with a reduced thickness, e.g., between 5-12 um, such as approximately 10 um, which can avoid potential chip gap height issues, i.e., issues related to the location of the top surface of the embedded interconnect bridge circuitry die 220 with respect to the top surface of the buildup layers 212. Mismatches in these heights can cause issues with connections to be made with integrated circuit dies above the die 220 or a top metallization layer of the buildup layer 212. Additional concerns of filling the cavity can also be present when attaching the interconnect bridge circuitry die 220 to the cavity 214. Any potential remaining height difference can be adjusted either in additional buildup layers to be formed or through thicker non-conductive film (NCF) around the die 220.

Other embodiments may avoid changes to the pads 221, 222 of the die and may instead incorporate a SF having the layer 302 be less than 500 nm thick, e.g., between 100-200 nm thick (e.g., 150 nm thick), which can avoid SJR issues through the inclusion of nickel, also avoid potential chip gap height concerns.

In other embodiments, the SF 216 may include the material stack shown in FIG. 4, which may be an immersion gold-electroless palladium-immersion gold (IGEPIG) SF. That is, the SF 216 may include a layer 402 comprising gold on the copper pad 215 in the cavity 214 of the package substrate, a layer 404 comprising palladium on the layer 402, and a layer 406 comprising gold on the layer 404. The layer 402 may be formed via immersion plating, the layer 404 may be formed via electroless plating, and the layer 406 may be formed by immersion plating, as the IGEPIG name implies. The layer 402 may be between 0.01-0.04 um (e.g., 0.02 um) thick, the layer 404 may be between 0.02-0.15 um (e.g., 0.10 um) thick, and the layer 406 may be between 0.03-0.10 um (e.g., 0.08 um) thick. These thickness, like the embodiment described above with a thinner nickel layer 302, can avoid chip gap height concerns with existing interconnect bridge circuitry die 220 implementations (e.g., those with pads being ˜15 μm thick). In addition, such embodiments can avoid gold embrittlement issues that can be seen with higher gold layer thicknesses in the gold-only plating approach.

Referring now to FIG. 2E, an interconnect bridge circuitry die 220 that includes TSVs 218 is placed within the cavity 214. The die 220 is attached using solder 223 such that at least certain of the bottom pads 221 of the die 220 are in electrical connection with the SFs 216 formed on the pads 215. Thereafter, a dielectric material (e.g., mold or buildup material) can be placed within the remaining portions of the cavity 214 to secure or encapsulate the interconnect bridge circuitry die 220, and further electrical contacts may be formed or placed into contact with the top pads 222, e.g., to connect one or more integrated circuit dies (e.g., 112 as shown in FIG. 1) to one another or to connect the integrated circuit dies with a circuit board (e.g., motherboard) below the substrate.

Although a bridge circuitry die is described herein, other types of dies may be embedded within a cavity of a package substrate as described herein. For example, active circuit dies (e.g., an integrated circuit die) or another type of die (e.g., a die with one or more passive circuit components, e.g., capacitors or inductors) may be embedded in accordance with embodiments herein instead of an interconnect bridge circuitry die to interconnect multiple integrated circuit dies.

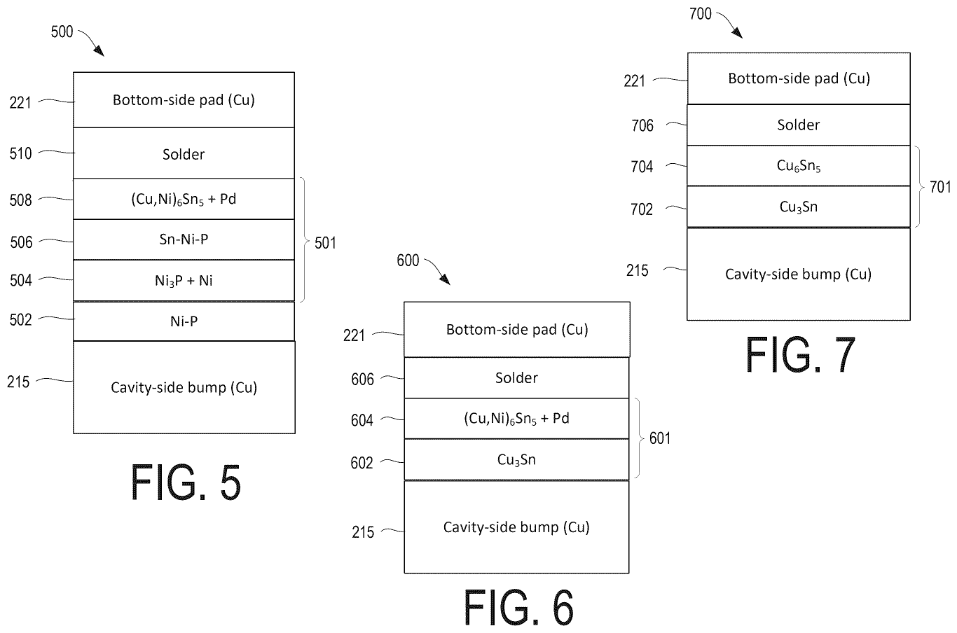

FIG. 5 illustrates an example material stack 500 that may be in an integrated circuit package after being manufactured according to the process of FIGS. 2A-2E with the material stack of FIG. 3. In particular, the FIG. 5 illustrates a cross-sectional diagram of an example solder joint between pads (e.g., 221) of a die (e.g. 220) and CSBs of a package substrate (e.g., 215) when ENEPIG with a relatively thick nickel layer (e.g., ˜7 um) is used as a surface finish. The solder 510 used may be tin-silver-copper (SnAgCu or SAC) solder or any other type of solder material, e.g., tin-silver or tin-copper solder chemistries. The solder may be flowed/reflowed at 250-270° C. in certain embodiments.

The example stack 500 includes IMCs 501 that are formed between the CSB pad 215 of the package substrate and solder 510 that is used to electrically connect the pads of a die (e.g., 221) to the pad 215. Although shown in particular layers, the IMCs 501 may be formed differently than shown. For example, the IMCs 501 may be interspersed or other IMCs may be present in the solder joint as well, e.g., Cu—Sn or Cu—Sn—Ni based IMCs.

The IMCs 501 are formed on a first layer 502 that includes nickel and phosphorous (Ni—P). The layer 502 may be the same or similar layer as layer 302 The IMCs 501 includes a first IMC 504 that also includes nickel and phosphorous (Ni₃P and Ni), a second IMC 506 that includes tin, nickel and phosphorous (Sn—Ni—P), and a third IMC that includes copper, nickel, tin ((Cu,Ni)₆Sn₅), and palladium. The layer 502 may include phosphorous at approximately 10-35% by weight, the first IMC 504 may include phosphorous at approximately 15-30% by weight, and the third IMC 506 may include copper at approximately 20-40% by weight, nickel at approximately 20-40% by weight, and tin at approximately 30-50% by weight.

A cross-section and elemental analysis metrology performed on the solder joint might reveal the presence of the (Cu, Ni)₆Sn₅ IMC (and/or the other IMCs shown) and may reveal the presence of nickel and phosphorous in the nickel and palladium plating layers of the ENEPIG (to ensure use of electroless technique). Additionally, because e-lytic NiPdAu SFs need DFR, they may form stacked cylinder-like shapes with sharp corners (similar to copper bumps/pads like 215). ENEPIG, however, may be plated without DFR and thus may plate conformally on all sides of the copper bump 215 with rounded corners (e.g., similar to the form shown in FIGS. 2D and 2E). Accordingly, it will be understood that the IMCs may be formed in the package substrate in a different form/shape than shown in FIG. 5.

FIG. 6 illustrates another example material stack 600 that may be in an integrated circuit package after being manufactured according to the process of FIGS. 2A-2E with the material stack of FIG. 3. In particular, the FIG. 6 illustrates a cross-sectional diagram of an example solder joint between pads (e.g., 221) of a die (e.g. 220) and CSBs of a package substrate (e.g., 215) when ENEPIG with a relatively thin nickel layer (e.g., ˜0.15 um) is used as a surface finish. The example stack 600 includes IMCs 601 that are formed between a copper pad 215 and the solder 606 (which may be any suitable solder material, e.g., SAC or another type of solder). Although shown in particular layers, the IMCs 5601 may be formed differently than shown, e.g., interspersed. Further, other IMCs may be present in the solder joint as well, e.g., Cu—Sn or Cu—Sn—Ni based IMCs.

The IMCs include a first IMC 602 that includes copper and tin (Cu₃Sn) and a second IMC 604 that includes copper, nickel, and tin ((Cu,Ni)₆Sn₅), and palladium. The first IMC 602 may include copper at approximately 60-75% by weight and tin at approximately 25-40% by weight. The second IMC 604 may include copper at approximately 30-50% by weight, nickel at approximately 10-30% by weight, and tin at approximately 30-50% by weight.

Similar to the previous example, a cross-section and elemental analysis metrology performed on the solder joint might reveal the presence of the (Cu,Ni)₆Sn₅ IMC, and may also reveal the presence of nickel from the use of the electroless technique for ENEPIG. Also, similar to the previous example, the ENEPIG may plate conformally on all sides of the copper bump 215 with rounded corners (e.g., similar to the form shown in FIGS. 2D and 2E). Accordingly, it will be understood that the IMCs may be formed in the package substrate in a different form/shape than shown in FIG. 6.

FIG. 7 illustrates an example material stack 700 that may be in an integrated circuit package after being manufactured according to the process of FIGS. 2A-2E with the material stack of FIG. 4. In particular, the FIG. 7 illustrates a cross-sectional diagram of an example solder joint between pads (e.g., 221) of a die (e.g. 220) and CSBs of a package substrate (e.g., 215) when IGEPIG is used as a surface finish. The example stack 700 includes IMCs 701 that are formed between a copper pad 215 and the solder 706 (which may be any suitable solder material, e.g., SAC or another type of solder). Although shown in particular layers, the IMCs 701 may be formed differently than shown. The IMCs include a first IMC 702 that includes copper and tin (Cu₃Sn) and a second IMC that also includes copper and tin, but in different form (Cu₆Sn₅). The first IMC 702 may include copper at approximately 60-75% by weight and tin at approximately 25-40% by weight, while the second IMC 704 may include copper at approximately 50-70% by weight and tin at approximately 30-50% by weight.

Similar to the previous examples, a cross-section and elemental analysis metrology performed on the cavity side bumps/package substrate might reveal the absence of nickel, e.g., in Ni—P or Ni₆Sn₅ IMCs in the solder joint. Also, similar to the previous examples, the IGEPIG may plate conformally on all sides of the copper bump 215 with rounded corners (e.g., similar to the form shown in FIGS. 2D and 2E). Accordingly, it will be understood that the IMCs may be formed in the package substrate in a different form/shape than shown in FIG. 7.

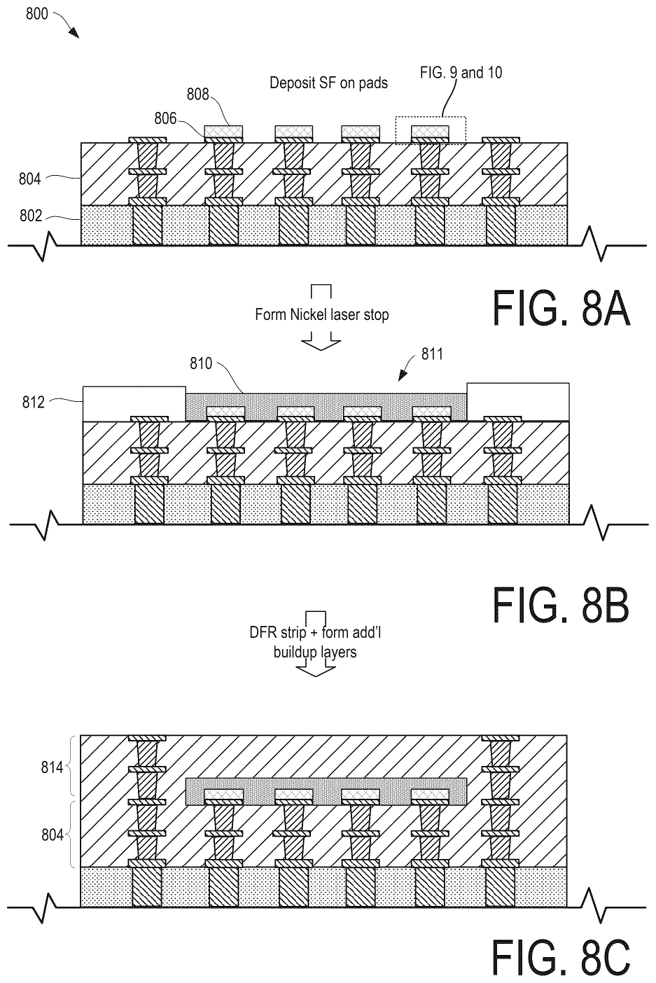

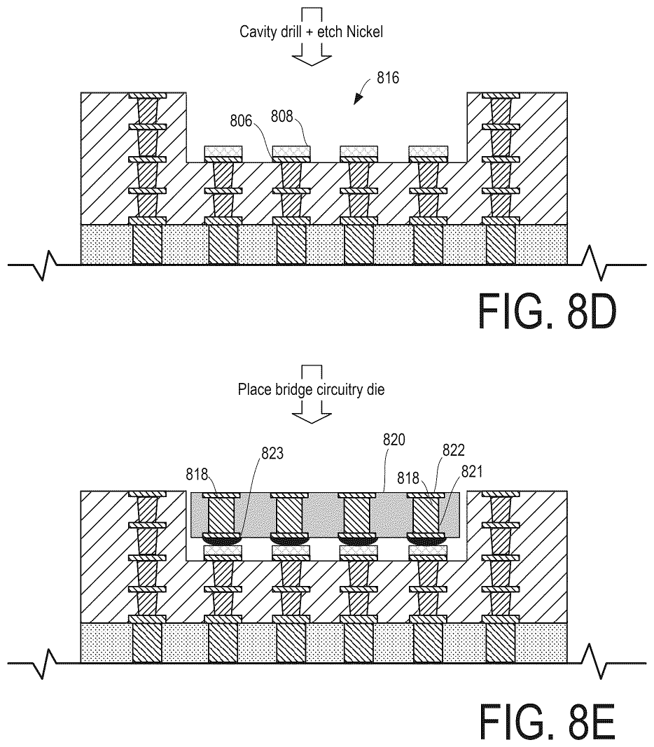

FIGS. 8A-8E illustrate a second example process 800 of embedding an interconnect bridge circuitry die in a package substrate in accordance with embodiments of the present disclosure. The process may include additional, fewer, or different operations than those shown or described below. In some embodiments, one or more of the operations shown include multiple operations, sub-operations, etc.

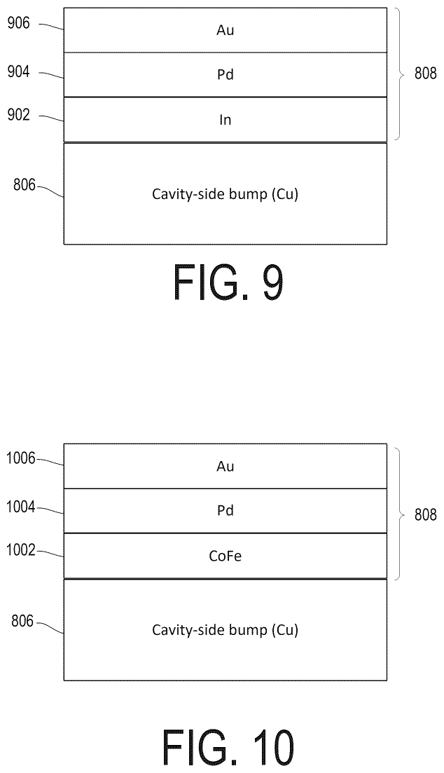

Referring to FIG. 8A, the example process 800 includes the formation of dielectric buildup layers 804 on a core layer 802 as shown. The buildup layers include metallization layers and pillars within the buildup layers 804 similar to the example described above with respect to FIG. 1. A surface finish (SF) 808 is then formed or deposited on exposed conductive pads 806 of the structure (e.g., those in the third metallization layer). The SF 808 may be formed with materials as shown in FIG. 9 or 10 and described further below.

For example, referring to FIG. 9, the SF 808 may include a layer 902 that includes indium that is deposited on the pads 806, with an electrolytic PdAu deposition on the layer 902. i.e., with a layer 904 that includes palladium on the layer 902 and a layer 906 that includes gold on the layer 904. In some embodiments, the layer 902 may be between 0.10-1 um thick, the layer 904 may be between 0.01-0.10 um thick (e.g., 0.04 um), and the layer 906 may be between 0.01-0.10 um thick (e.g., 0.06 um). The layer 902 may include indium at approximately 2-8% by weight (e.g., 5% by weight).

A thin indium layer such as 902 may provide a small change in the overall thickness of the SF 808 as compared with current process flows, and thus, might not cause chip gap height issues and can be implemented in current process flows with relatively little impact. In addition, an indium layer such as 902 can act as an active electromigration suppressor by backfilling electron voids created by tin during soldering. Thinner layers 902 (e.g., those closer to the 100 nm thickness) can provide improved Imax characteristics, while thicker layer 902 (e.g., those closer to the 1 um thickness) can also provide properties of a low temperature solder.

As another example, referring to FIG. 10, the SF 808 may include a layer 1002 that includes cobalt and iron (CoFe) that is deposited on the pads 806, with an electrolytic PdAu deposition on the layer 1002. i.e., with a layer 1004 that includes palladium on the layer 1002 and a layer 1006 that includes gold on the layer 1004. In some embodiments, the layer 1002 may be between 2-4 um thick (e.g., 3.3 um), the layer 1004 may be between 0.01-0.10 um thick (e.g., 0.04 um), and the layer 1006 may be between 0.01-0.10 um thick (e.g., 0.06 um). The layer 1002 may include cobalt at approximately 20-35% by weight and iron at approximately 65-80% by weight.

A layer having cobalt and iron, such as 1002, may have little to no change in properties with dopants, and thus, may be compatible with the palladium and gold deposited on it as in the examples shown in FIG. 10. Further, cobalt and iron may provide IMC formation kinetics that are better than those that include other materials, e.g., slower growth in comparison to layers with nickel, allowing for potentially improved SJR than nickel-inclusive SFs. The overall thickness of the examples described (e.g., between 3-4 um) may be consistent with current processes, and thus might not cause chip gap height issues and can be incorporated into existing process flows with relatively little cost or changes.

Referring now to FIG. 8B, a laser stop layer 810 is then formed within an opening 811 in a photoresist layer 812 (e.g., a dry film resist (DFR) layer) on the buildup layers 804. The laser stop layer 810 may include nickel or any other suitable material. Then, as shown in FIG. 8C, the photoresist layer 812 is removed and additional buildup layers 814 are formed on the buildup layers 804 as shown, including forming the dielectric buildup layer in the area above the laser stop layer 810. Then, as shown in FIG. 8D, a cavity 816 is formed (e.g., via laser drilling) in the area above the laser stop layer 810 until the laser stop layer 810 is exposed. The laser stop layer 810 can then be removed (e.g., etched) to expose the SF 808 on the conductive pads 806.

Referring now to FIG. 8E, an interconnect bridge circuitry die 820 that includes TSVs 818 is placed within the cavity 816. The die 820 is attached using solder 823 such that at least certain of the bottom pads 821 of the die 820 are in electrical connection with the SFs 808 formed on the pads 806. Thereafter, a dielectric (e.g., a mold or buildup material) can be placed within the remaining portions of the cavity 816 to secure or encapsulate the interconnect bridge circuitry die 820, and further electrical contacts may be formed or placed into contact with the top pads 822 of the die 820, e.g., to connect one or more integrated circuit dies (e.g., 112 as shown in FIG. 1) to one another or to connect the integrated circuit dies with a circuit board (e.g., motherboard) below the substrate.

Although a bridge circuitry die is described herein, other types of dies may be embedded within a cavity of a package substrate as described herein. For example, active circuit dies (e.g., an integrated circuit die) or another type of die (e.g., a die with one or more passive circuit components, e.g., capacitors or inductors) may be embedded in accordance with embodiments herein instead of an interconnect bridge circuitry die to interconnect multiple integrated circuit dies.

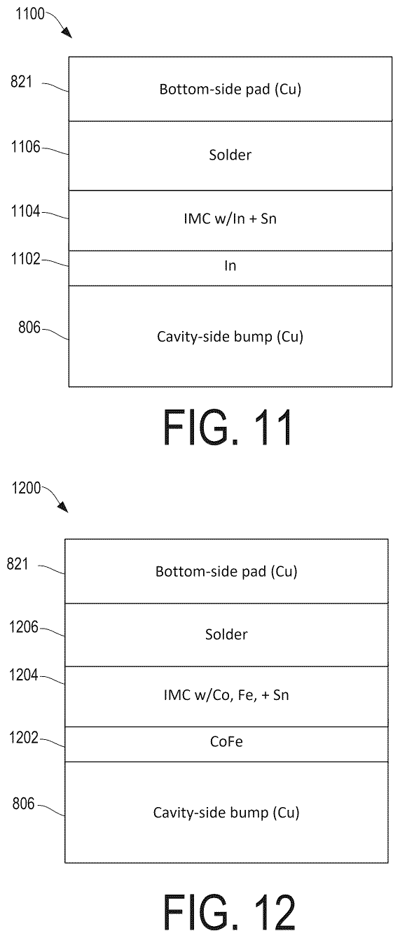

FIG. 11 illustrates an example material stack 1100 that may be in an integrated circuit package after being manufactured according to the process of FIGS. 8A-8E with the material stack of FIG. 9. In particular, the FIG. 11 illustrates a cross-sectional diagram of an example solder joint between pads (e.g., 821) of a die (e.g. 820) and CSBs of a package substrate (e.g., 806) when a surface finish of FIG. 9 is used. The example stack 1100 includes an IMC 1104 that is formed between the layer 1102 comprising indium and the solder 1106 (which may be any suitable solder material, e.g., SAC or another type of solder). The IMC 1104 may include indium at approximately 1-5% by weight and tin at approximately 95-99% by weight. In certain embodiments, the stack 1100 may have a generally cylindrical shape, as an SF as described with respect to FIG. 9 may be formed using photoresist (e.g., DFR).

FIG. 12 illustrates an example material stack 1200 that may be in an integrated circuit package after being manufactured according to the process of FIGS. 8A-8E with the material stack of FIG. 10. In particular, the FIG. 12 illustrates a cross-sectional diagram of an example solder joint between pads (e.g., 821) of a die (e.g. 820) and CSBs of a package substrate (e.g., 806) when a surface finish of FIG. 10 is used. The example stack 1200 includes an IMC 1204 that is formed between the layer 1202 comprising cobalt and iron and the solder 1206 (which may be any suitable solder material, e.g., SAC or another type of solder). The IMC 1104 may include cobalt at approximately 2-8% by weight, iron at approximately 10-30% by weight, and tin at approximately 65-85% by weight. In certain embodiments, the stack 1200 may have a generally cylindrical shape, as an SF as described with respect to FIG. 10 may be formed using photoresist (e.g., DFR).

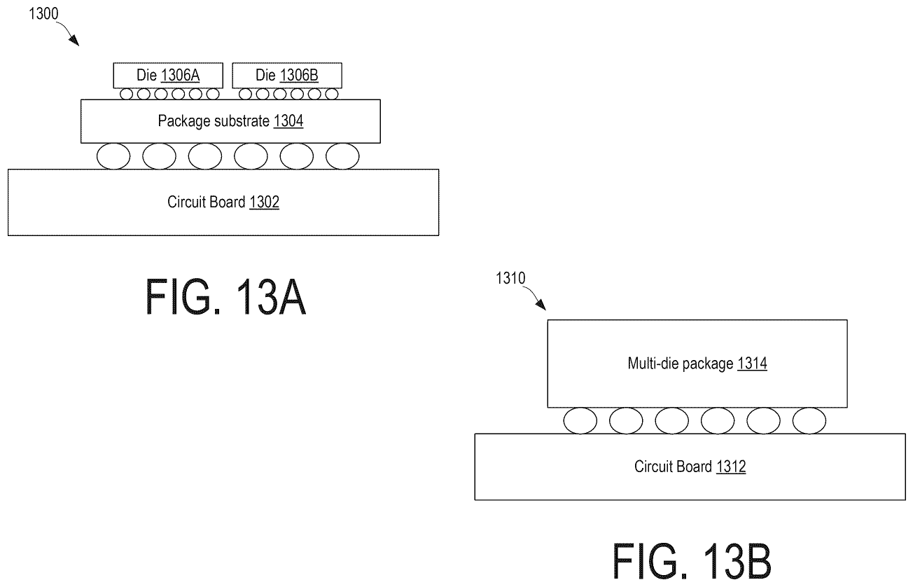

FIGS. 13A-13B illustrate example systems 1300, 1310 that may incorporate the architectures described herein. In particular, the package substrate 1304 and the multi-die package 1314 may include conductive contacts with surface finishes as described herein to connect to an embedded component, e.g., an interconnect bridge circuitry die, within the substrate 1304 or within layers of the package 1314.

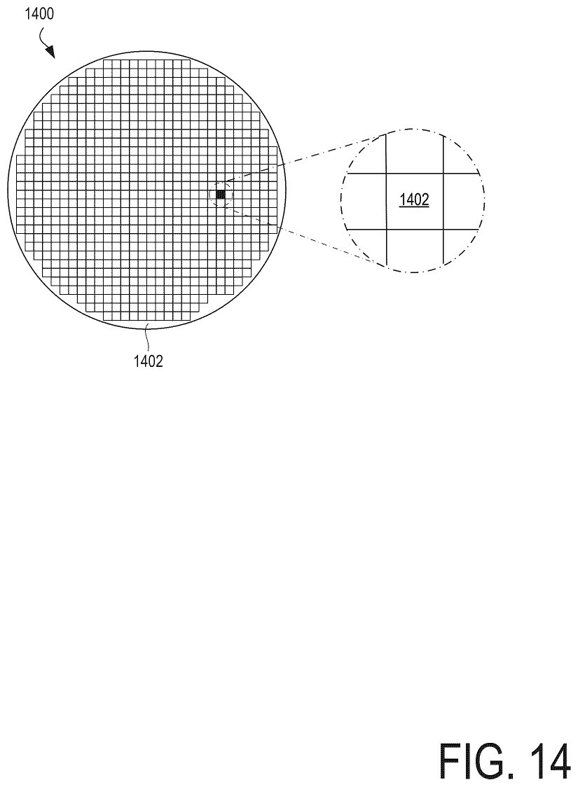

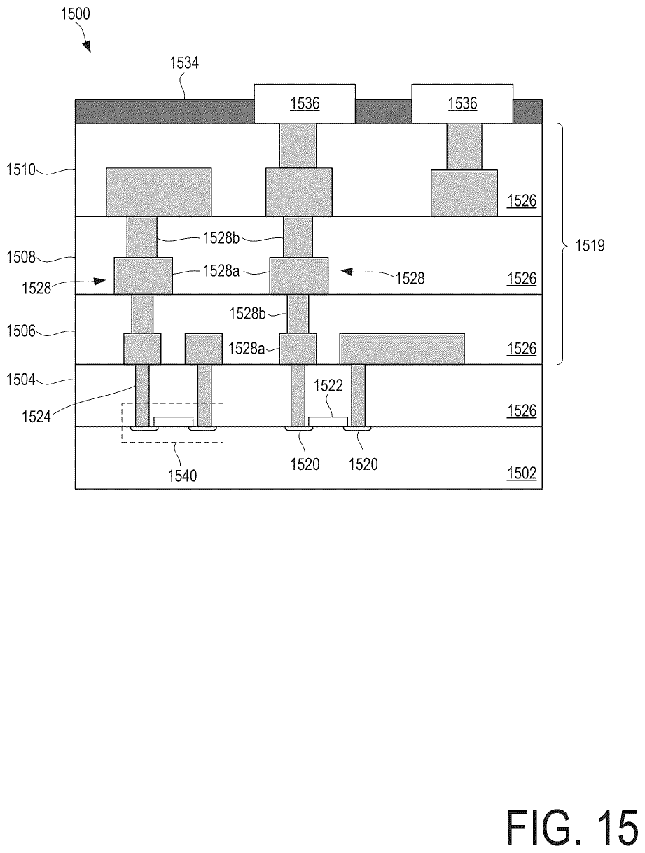

The example system 1300 of FIG. 13A includes a circuit board 1302, which may be implemented as a motherboard or main board of a computer system in some embodiments. The example system 1300 also includes a package substrate 1304 with integrated circuit dies 1306A, 1306B attached to the package substrate 1304. The dies 1306 may be packaged or unpacked integrated circuit products that include one or more integrated circuit dies (e.g., the die 1402 of FIG. 14, the integrated circuit device 1500 of FIG. 15) and/or one or more other suitable components. The die 1306 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 1306 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 1306 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 1304 may provide electrical connections between the die 1306 and the circuit board 1302 and may include an embedded interconnect bridge circuitry die as described above.

Similar to the system 1300, the system 1310 also includes a circuit board 1312, which may be implemented as a motherboard or main board of a computer system in some embodiments. The system 1310 also includes a multi-die package 1314, which includes multiple integrated circuits/dies (e.g., 1306), and interconnections between the dies in one or more metallization layers. The multi-die package 1314 may include, for example, one or more silicon interposers, one or more silicon bridges embedded in the package substrate. For example, the package 1314 may include an embedded interconnect bridge circuitry die (e.g., an Intel® embedded multi-die interconnect bridge (EMIB) as described above.

The main circuit boards 1302, 1312 may provide electrical connections to other components of a computer system, e.g., memory, storage, network interfaces, peripheral devices, power supplies, etc. The main circuit board may include one or more traces and circuit components to provide interconnects between such computer system components.

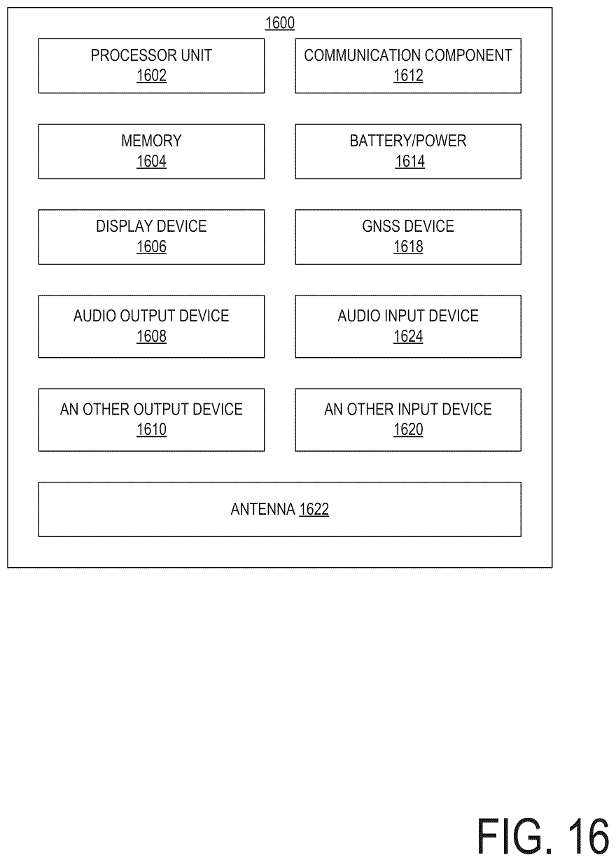

FIG. 14 is a top view of a wafer 1400 and dies 1402 that may incorporate any of the embodiments disclosed herein. The wafer 1400 may be composed of semiconductor material and may include one or more dies 1402 having integrated circuit structures formed on a surface of the wafer 1400. The individual dies 1402 may be a repeating unit of an integrated circuit product that includes any suitable integrated circuit. After the fabrication of the semiconductor product is complete, the wafer 1400 may undergo a singulation process in which the dies 1402 are separated from one another to provide discrete “chips” of the integrated circuit product. The die 1402 may include one or more transistors (e.g., some of the transistors 1540 of FIG. 15, discussed below), supporting circuitry to route electrical signals to the transistors, passive components (e.g., signal traces, resistors, capacitors, or inductors), and/or any other integrated circuit components. In some embodiments, the wafer 1400 or the die 1402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1402. For example, a memory array formed by multiple memory devices may be formed on a same die 1402 as a processor unit (e.g., the processor unit 1602 of FIG. 16) or other logic that is configured to store information in the memory devices or execute instructions stored in the memory array.

FIG. 15 is a cross-sectional side view of an integrated circuit device 1500 that may be included in any of the embodiments disclosed herein. One or more of the integrated circuit devices 1500 may be included in one or more dies 1402 (FIG. 14). The integrated circuit device 1500 may be formed on a die substrate 1502 (e.g., the wafer 1400 of FIG. 14) and may be included in a die (e.g., the die 1402 of FIG. 14). The die substrate 1502 may be a semiconductor substrate composed of semiconductor material systems including, for example, n-type or p-type materials systems (or a combination of both). The die substrate 1502 may include, for example, a crystalline substrate formed using a bulk silicon or a silicon-on-insulator (SOI) substructure. In some embodiments, the die substrate 1502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1502. Although a few examples of materials from which the die substrate 1502 may be formed are described here, any material that may serve as a foundation for an integrated circuit device 1500 may be used. The die substrate 1502 may be part of a singulated die (e.g., the dies 1402 of FIG. 14) or a wafer (e.g., the wafer 1400 of FIG. 14).

The integrated circuit device 1500 may include one or more device layers 1504 disposed on the die substrate 1502. The device layer 1504 may include features of one or more transistors 1540 (e.g., metal oxide semiconductor field-effect transistors (MOSFETs) or ferroelectric field-effect transistors (FeFETs), e.g., those described herein) formed on the die substrate 1502. The transistors 1540 may include, for example, one or more source and/or drain (S/D) regions 1520, a gate 1522 to control current flow between the S/D regions 1520, and one or more S/D contacts 1524 to route electrical signals to/from the S/D regions 1520. The transistors 1540 may include additional features not depicted for the sake of clarity, such as device isolation regions, gate contacts, and the like. The transistors 1540 are not limited to the type and configuration depicted in FIG. 15 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 15, the example transistor 1540 may include a gate 1522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1540 along the source-channel-drain direction, the gate electrode may consist of a U-shaped structure that includes a bottom portion substantially parallel to the surface of the die substrate 1502 and two sidewall portions that are substantially perpendicular to the top surface of the die substrate 1502. In other embodiments, at least one of the metal layers that form the gate electrode may simply be a planar layer that is substantially parallel to the top surface of the die substrate 1502 and does not include sidewall portions substantially perpendicular to the top surface of the die substrate 1502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1520 may be formed within the die substrate 1502 adjacent to the gate 1522 of individual transistors 1540. The S/D regions 1520 may be formed using an implantation/diffusion process or an etching/deposition process, for example. In the former process, dopants such as boron, aluminum, antimony, phosphorous, or arsenic may be ion-implanted into the die substrate 1502 to form the S/D regions 1520. An annealing process that activates the dopants and causes them to diffuse farther into the die substrate 1502 may follow the ion-implantation process. In the latter process, the die substrate 1502 may first be etched to form recesses at the locations of the S/D regions 1520. An epitaxial deposition process may then be carried out to fill the recesses with material that is used to fabricate the S/D regions 1520. In some implementations, the S/D regions 1520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1520 may be formed using one or more alternate semiconductor materials such as germanium or a group III-V material or alloy. In further embodiments, one or more layers of metal and/or metal alloys may be used to form the S/D regions 1520.

Electrical signals, such as power and/or input/output (I/O) signals, may be routed to and/or from the devices (e.g., transistors 1540) of the device layer 1504 through one or more interconnect layers disposed on the device layer 1504 (illustrated in FIG. 15 as interconnect layers 1506-1510). For example, electrically conductive features of the device layer 1504 (e.g., the gate 1522 and the S/D contacts 1524) may be electrically coupled with the interconnect structures 1528 of the interconnect layers 1506-1510. The one or more interconnect layers 1506-1510 may form a metallization stack (also referred to as an “ILD stack”) 1519 of the integrated circuit device 1500.

The interconnect structures 1528 may be arranged within the interconnect layers 1506-1510 to route electrical signals according to a wide variety of designs; in particular, the arrangement is not limited to the particular configuration of interconnect structures 1528 depicted in FIG. 15. Although a particular number of interconnect layers 1506-1510 is depicted in FIG. 15, embodiments of the present disclosure include integrated circuit devices having more or fewer interconnect layers than depicted.

In some embodiments, the interconnect structures 1528 may include lines 1528a and/or vias 1528b filled with an electrically conductive material such as a metal. The lines 1528a may be arranged to route electrical signals in a direction of a plane that is substantially parallel with a surface of the die substrate 1502 upon which the device layer 1504 is formed. For example, the lines 1528a may route electrical signals in a direction in and out of the page and/or in a direction across the page from the perspective of FIG. 15. The vias 1528b may be arranged to route electrical signals in a direction of a plane that is substantially perpendicular to the surface of the die substrate 1502 upon which the device layer 1504 is formed. In some embodiments, the vias 1528b may electrically couple lines 1528a of different interconnect layers 1506-1510 together.

The interconnect layers 1506-1510 may include a dielectric material 1526 disposed between the interconnect structures 1528, as shown in FIG. 15. In some embodiments, dielectric material 1526 disposed between the interconnect structures 1528 in different ones of the interconnect layers 1506-1510 may have different compositions; in other embodiments, the composition of the dielectric material 1526 between different interconnect layers 1506-1510 may be the same. The device layer 1504 may include a dielectric material 1526 disposed between the transistors 1540 and a bottom layer of the metallization stack as well. The dielectric material 1526 included in the device layer 1504 may have a different composition than the dielectric material 1526 included in the interconnect layers 1506-1510; in other embodiments, the composition of the dielectric material 1526 in the device layer 1504 may be the same as a dielectric material 1526 included in any one of the interconnect layers 1506-1510.

A first interconnect layer 1506 (referred to as Metal 1 or “M1”) may be formed directly on the device layer 1504. In some embodiments, the first interconnect layer 1506 may include lines 1528a and/or vias 1528b, as shown. The lines 1528a of the first interconnect layer 1506 may be coupled with contacts (e.g., the S/D contacts 1524) of the device layer 1504. The vias 1528b of the first interconnect layer 1506 may be coupled with the lines 1528a of a second interconnect layer 1508.

The second interconnect layer 1508 (referred to as Metal 2 or “M2”) may be formed directly on the first interconnect layer 1506. In some embodiments, the second interconnect layer 1508 may include via 1528b to couple the lines 1528 of the second interconnect layer 1508 with the lines 1528a of a third interconnect layer 1510. Although the lines 1528a and the vias 1528b are structurally delineated with a line within individual interconnect layers for the sake of clarity, the lines 1528a and the vias 1528b may be structurally and/or materially contiguous (e.g., simultaneously filled during a dual-damascene process) in some embodiments.

The third interconnect layer 1510 (referred to as Metal 3 or “M3”) (and additional interconnect layers, as desired) may be formed in succession on the second interconnect layer 1508 according to similar techniques and configurations described in connection with the second interconnect layer 1508 or the first interconnect layer 1506. In some embodiments, the interconnect layers that are “higher up” in the metallization stack 1519 in the integrated circuit device 1500 (i.e., farther away from the device layer 1504) may be thicker that the interconnect layers that are lower in the metallization stack 1519, with lines 1528a and vias 1528b in the higher interconnect layers being thicker than those in the lower interconnect layers.

The integrated circuit device 1500 may include a solder resist material 1534 (e.g., polyimide or similar material) and one or more conductive contacts 1536 formed on the interconnect layers 1506-1510. In FIG. 15, the conductive contacts 1536 are illustrated as taking the form of bond pads. The conductive contacts 1536 may be electrically coupled with the interconnect structures 1528 and configured to route the electrical signals of the transistor(s) 1540 to external devices. For example, solder bonds may be formed on the one or more conductive contacts 1536 to mechanically and/or electrically couple an integrated circuit dic including the integrated circuit device 1500 with another component (e.g., a printed circuit board). The integrated circuit device 1500 may include additional or alternate structures to route the electrical signals from the interconnect layers 1506-1510; for example, the conductive contacts 1536 may include other analogous features (e.g., posts) that route the electrical signals to external components.

In some embodiments in which the integrated circuit device 1500 is a double-sided die, the integrated circuit device 1500 may include another metallization stack (not shown) on the opposite side of the device layer(s) 1504. This metallization stack may include multiple interconnect layers as discussed above with reference to the interconnect layers 1506-1510, to provide conductive pathways (e.g., including conductive lines and vias) between the device layer(s) 1504 and additional conductive contacts (not shown) on the opposite side of the integrated circuit device 1500 from the conductive contacts 1536.

In other embodiments in which the integrated circuit device 1500 is a double-sided die, the integrated circuit device 1500 may include one or more through silicon vias (TSVs) through the die substrate 1502; these TSVs may make contact with the device layer(s) 1504, and may provide conductive pathways between the device layer(s) 1504 and additional conductive contacts (not shown) on the opposite side of the integrated circuit device 1500 from the conductive contacts 1536. In some embodiments, TSVs extending through the substrate can be used for routing power and ground signals from conductive contacts on the opposite side of the integrated circuit device 1500 from the conductive contacts 1536 to the transistors 1540 and any other components integrated into the die 1500, and the metallization stack 1519 can be used to route I/O signals from the conductive contacts 1536 to transistors 1540 and any other components integrated into the die 1500.

Multiple integrated circuit devices 1500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 16 is a block diagram of an example electrical device 1600 that may include one or more of the embodiments disclosed herein. For example, any suitable ones of the components of the electrical device 1600 may include one or more of the integrated circuit devices 1500 or integrated circuit dies 1402 disclosed herein. A number of components are illustrated in FIG. 16 as included in the electrical device 1600, but any one or more of these components may be omitted or duplicated, as suitable for the application. In some embodiments, some or all of the components included in the electrical device 1600 may be attached to one or more motherboards mainboards, or system boards. In some embodiments, one or more of these components are fabricated onto a single system-on-a-chip (SoC) die.

Additionally, in various embodiments, the electrical device 1600 may not include one or more of the components illustrated in FIG. 16, but the electrical device 1600 may include interface circuitry for coupling to the one or more components. For example, the electrical device 1600 may not include a display device 1606, but may include display device interface circuitry (e.g., a connector and driver circuitry) to which a display device 1606 may be coupled. In another set of examples, the electrical device 1600 may not include an audio input device 1624 or an audio output device 1608, but may include audio input or output device interface circuitry (e.g., connectors and supporting circuitry) to which an audio input device 1624 or audio output device 1608 may be coupled.

The electrical device 1600 may include one or more processor units 1602 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1602 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1600 may include a memory 1604, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1604 may include memory that is located on the same integrated circuit die as the processor unit 1602. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1600 can comprise one or more processor units 1602 that are heterogeneous or asymmetric to another processor unit 1602 in the electrical device 1600. There can be a variety of differences between the processing units 1602 in a system in terms of a spectrum of metrics of merit including architectural, microarchitectural, thermal, power consumption characteristics, and the like. These differences can effectively manifest themselves as asymmetry and heterogeneity among the processor units 1602 in the electrical device 1600.

In some embodiments, the electrical device 1600 may include a communication component 1612 (e.g., one or more communication components). For example, the communication component 1612 can manage wireless communications for the transfer of data to and from the electrical device 1600. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1612 may operate in accordance with other wireless protocols in other embodiments. The electrical device 1600 may include an antenna 1622 to facilitate wireless communications and/or to receive other wireless communications (such as AM or FM radio transmissions).

In some embodiments, the communication component 1612 may manage wired communications, such as electrical, optical, or any other suitable communication protocols (e.g., IEEE 802.3 Ethernet standards). As noted above, the communication component 1612 may include multiple communication components. For instance, a first communication component 1612 may be dedicated to shorter-range wireless communications such as Wi-Fi or Bluetooth, and a second communication component 1612 may be dedicated to longer-range wireless communications such as global positioning system (GPS), EDGE, GPRS, CDMA, WiMAX, LTE, EV-DO, or others. In some embodiments, a first communication component 1612 may be dedicated to wireless communications, and a second communication component 1612 may be dedicated to wired communications.

The electrical device 1600 may include battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include a display device 1606 (or corresponding interface circuitry, as discussed above). The display device 1606 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1600 may include an audio output device 1608 (or corresponding interface circuitry, as discussed above). The audio output device 1608 may include any embedded or wired or wirelessly connected external device that generates an audible indicator, such speakers, headsets, or earbuds.

The electrical device 1600 may include an audio input device 1624 (or corresponding interface circuitry, as discussed above). The audio input device 1624 may include any embedded or wired or wirelessly connected device that generates a signal representative of a sound, such as microphones, microphone arrays, or digital instruments (e.g., instruments having a musical instrument digital interface (MIDI) output). The electrical device 1600 may include a Global Navigation Satellite System (GNSS) device 1618 (or corresponding interface circuitry, as discussed above), such as a Global Positioning System (GPS) device. The GNSS device 1618 may be in communication with a satellite-based system and may determine a geolocation of the electrical device 1600 based on information received from one or more GNSS satellites, as known in the art.

The electrical device 1600 may include an other output device 1610 (or corresponding interface circuitry, as discussed above). Examples of the other output device 1610 may include an audio codec, a video codec, a printer, a wired or wireless transmitter for providing information to other devices, or an additional storage device.

The electrical device 1600 may include another input device 1620 (or corresponding interface circuitry, as discussed above). Examples of the other input device 1620 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1600 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1600 may be any other electronic device that processes data. In some embodiments, the electrical device 1600 may comprise multiple discrete physical components. Given the range of devices that the electrical device 1600 can be manifested as in various embodiments, in some embodiments, the electrical device 1600 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example A1 is an integrated circuit package substrate comprising: a plurality of metallization layers in dielectric buildup layers; a die within the buildup layers, the die comprising a conductive contact in electrical connection with a conductive contact of a metallization layer; and conductive materials between the conductive contact of the die and the conductive contact of the metallization layer, the conductive materials comprising nickel, phosphorous, tin, and palladium.

Example A2 includes the subject matter of Example A1, wherein the conductive materials comprise an intermetallic compound comprising nickel and phosphorous.

Example A3 includes the subject matter of Example A2, wherein the intermetallic compound comprises phosphorous at between 15-30% by weight.

Example A4 includes the subject matter of any one of Examples A1-A3, wherein the conductive materials comprise an intermetallic compound comprising copper, nickel, tin, and palladium.

Example A5 includes the subject matter of Example A4, wherein the intermetallic compound comprises copper at between 20-40% by weight, nickel at between 20-40% by weight, and tin at between 30-50% by weight.

Example A6 includes the subject matter of any one of Examples A1-A5, wherein the conductive materials comprise an intermetallic compound comprising nickel, tin, and phosphorous.

Example A7 includes the subject matter of any one of Examples A1-A6, wherein the conductive materials comprise a layer on the conductive pads of the metallization layer comprising nickel and phosphorous.

Example A8 includes the subject matter of any one of Examples A1-A7, wherein the die is an interconnect bridge circuitry die.

Example A9 includes the subject matter of Example A8, wherein the interconnect bridge circuitry die comprises a through silicon via (TSV) connected to the conductive contact of the die.

Example A10 includes the subject matter of any one of Examples A1-A9, wherein the die is encapsulated in a cavity or opening in the buildup layers.

Example A11 is an integrated circuit package comprising: an integrated circuit package substrate comprising: a plurality of metallization layers in dielectric buildup layers; an interconnect bridge circuitry die embedded in the buildup layers, the interconnect bridge circuitry die comprising a via connected between a first conductive contact on a first side of the interconnect bridge circuitry die and a second conductive contact on a second side of the interconnect bridge circuitry die opposite the first side, the second conductive contact in electrical connection with a conductive contact of a metallization layer; and conductive materials between the second conductive contact of the interconnect bridge circuitry die and the conductive contact of the metallization layer, the conductive materials comprising nickel, phosphorous, tin, and palladium; and integrated circuit dies coupled to the package substrate, at least two integrated circuit dies interconnected by the interconnect bridge circuitry die.

Example A12 includes the subject matter of Example A11, wherein the conductive materials comprise an intermetallic compound comprising nickel and phosphorous.

Example A13 includes the subject matter of Example A12, wherein the intermetallic compound comprises phosphorous at between 15-30% by weight.

Example A14 includes the subject matter of any one of Examples A11-A13, wherein the conductive materials comprise an intermetallic compound comprising copper, nickel, tin, and palladium.

Example A15 includes the subject matter of Example A14, wherein the intermetallic compound comprises copper at between 20-40% by weight, nickel at between 20-40% by weight, and tin at between 30-50% by weight.

Example A16 includes the subject matter of any one of Examples A11-A15, wherein the conductive materials comprise an intermetallic compound comprising nickel, tin, and phosphorous.

Example A17 includes the subject matter of any one of Examples A11-A16, wherein the conductive materials comprise a layer on the conductive pads of the metallization layer comprising nickel and phosphorous.

Example A18 is an method of forming an integrated circuit package substrate comprising: forming buildup layers on a core layer, the buildup layers comprising a plurality of metallization layers; forming a cavity in the buildup layers to expose a subset of conductive contacts of a metallization layer; forming a first surface finish layer on the subset of conductive contacts, the first surface finish layer comprising nickel and having a thickness that is greater than 5 um; forming a second surface finish layer on the first surface finish layer, the second surface finish layer comprising palladium; forming a third surface finish layer on the second surface finish layer, the second surface finish layer comprising gold; placing a die within the cavity such that conductive contacts of the die are in electrical connection with the subset of conductive contacts.

Example A19 includes the subject matter of Example A18, wherein the first surface finish layer is formed using electroless plating, the second surface finish layer is formed using electroless plating, and the third surface finish layer is formed using immersion plating.

Example A20 includes the subject matter of Example A18 or A19, wherein the first surface finish layer is between 5-10 um thick, the second surface finish layer is between 0.01-0.10 μm thick, and the third surface finish layer is between 0.01-0.10 μm thick.

Example B1 is an integrated circuit package substrate comprising: a plurality of metallization layers in dielectric buildup layers; a die within the buildup layers, the die comprising a conductive contact in electrical connection with a conductive contact of a metallization layer; and conductive materials between the conductive contact of the die and the conductive contact of the metallization layer, the conductive materials comprising copper, nickel, tin, and palladium.

Example B2 includes the subject matter of Example B1, wherein the conductive materials comprise an intermetallic compound comprising copper and tin.

Example B3 includes the subject matter of Example B2, wherein the intermetallic compound comprises copper at between 60-75% by weight and tin at between 25-40% by weight.

Example B4 includes the subject matter of any one of Examples B1-B3, wherein the conductive materials comprise an intermetallic compound comprising copper, nickel, tin, and palladium.

Example B5 includes the subject matter of Example B4, wherein the intermetallic compound comprises copper at between 30-50% by weight, nickel at between 10-30% by weight, and tin at between 30-50% by weight.

Example B6 includes the subject matter of any one of Examples B1-B5, wherein the die is an interconnect bridge circuitry die.

Example B7 includes the subject matter of Example B6, wherein the interconnect bridge circuitry die comprises a through silicon via (TSV) connected to the conductive contact of the die.

Example B8 includes the subject matter of any one of Examples B1-B7, wherein the conductive materials are conformally around the conductive contact of the metallization layer.

Example B9 is an integrated circuit package comprising: an integrated circuit package substrate comprising: a plurality of metallization layers in dielectric buildup layers; an interconnect bridge circuitry die embedded in the buildup layers, the interconnect bridge circuitry die comprising a via connected between a first conductive contact on a first side of the interconnect bridge circuitry die and a second conductive contact on a second side of the interconnect bridge circuitry die opposite the first side, the second conductive contact in electrical connection with a conductive contact of a metallization layer; and conductive materials between the second conductive contact of the interconnect bridge circuitry die and the conductive contact of the metallization layer, the conductive materials comprising copper, nickel, tin, and palladium; and integrated circuit dies coupled to the package substrate, at least two integrated circuit dies interconnected by the interconnect bridge circuitry die.

Example B10 includes the subject matter of Example B9, wherein the conductive materials comprise an intermetallic compound comprising copper and tin.

Example B11 includes the subject matter of Example B10, wherein the intermetallic compound comprises copper at between 60-75% by weight and tin at between 25-40% by weight.

Example B12 includes the subject matter of any one of Examples B9-B11, wherein the conductive materials comprise an intermetallic compound comprising copper, nickel, tin, and palladium.

Example B13 includes the subject matter of Example B12, wherein the intermetallic compound comprises copper at between 30-50% by weight, nickel at between 10-30% by weight, and tin at between 30-50% by weight.

Example B14 includes the subject matter of any one of Examples B9-B13, wherein the second conductive contact of the interconnect bridge circuitry die has a thickness greater than 12 um.

Example B15 includes the subject matter of any one of Examples B9-B14, wherein the conductive materials are conformally around the conductive contact of the metallization layer.

Example B16 is a method of forming an integrated circuit package substrate comprising: forming buildup layers on a core layer, the buildup layers comprising a plurality of metallization layers; forming a cavity in the buildup layers to expose a subset of conductive contacts of a metallization layer; forming a first surface finish layer on the subset of conductive contacts, the first surface finish layer comprising nickel and having a thickness that is less than 500 nm; forming a second surface finish layer on the first surface finish layer, the second surface finish layer comprising palladium; forming a third surface finish layer on the second surface finish layer, the second surface finish layer comprising gold; placing a die within the cavity such that conductive contacts of the die are in electrical connection with the subset of conductive contacts.

Example B17 includes the subject matter of Example B16, wherein the first surface finish layer is formed using electroless plating, the second surface finish layer is formed using electroless plating, and the third surface finish layer is formed using immersion plating.

Example B18 includes the subject matter of Example B16 or B17, wherein the first surface finish layer is between 100-200 nm thick, the second surface finish layer is between 0.01-0.10 μm thick, and the third surface finish layer is between 0.01-0.10 μm thick.

Example B19 includes the subject matter of Example B18, wherein the first surface finish layer is approximately 150 nm thick, the second surface finish layer is approximately 0.04 um thick, and the third surface finish layer is approximately 0.06 um thick.

Example B20 includes the subject matter of any one of Examples B16-B19, wherein the first surface finish layer is formed conformally around each conductive contact of the subset of conductive contacts.

Example C1 is an integrated circuit package substrate comprising: a plurality of metallization layers in dielectric buildup layers; a die within the buildup layers, the die comprising a conductive contact in electrical connection with a conductive contact of a metallization layer; and conductive materials between the conductive contact of the die and the conductive contact of the metallization layer, the conductive materials comprising copper and tin.

Example C2 includes the subject matter of Example C1, wherein the conductive materials comprise an intermetallic compound comprising copper and tin.

Example C3 includes the subject matter of Example C2, wherein the intermetallic compound comprises copper at between 60-75% by weight and tin at between 25-40% by weight.

Example C4 includes the subject matter of Example C2, wherein the intermetallic compound is a first intermetallic compound, and the conductive materials further comprise a second intermetallic compound comprising copper and tin.

Example C5 includes the subject matter of Example C4, wherein the second intermetallic compound comprises copper at between 50-70% by weight and tin at between 30-50% by weight.

Example C6 includes the subject matter of any one of Examples C1-C5, wherein the conductive materials do not include nickel.

Example C7 includes the subject matter of any one of Examples C1-C6, wherein the die is an interconnect bridge circuitry die.

Example C8 includes the subject matter of Example C7, wherein the interconnect bridge circuitry die comprises a through silicon via (TSV) connected to the conductive contact of the die.

Example C9 is an integrated circuit package comprising: an integrated circuit package substrate comprising: a plurality of metallization layers in dielectric buildup layers; an interconnect bridge circuitry die embedded in the buildup layers, the interconnect bridge circuitry die comprising a via connected between a first conductive contact on a first side of the interconnect bridge circuitry die and a second conductive contact on a second side of the interconnect bridge circuitry die opposite the first side, the second conductive contact in electrical connection with a conductive contact of a metallization layer; and conductive materials between the second conductive contact of the interconnect bridge circuitry die and the conductive contact of the metallization layer, the conductive materials comprising copper and tin; and integrated circuit dies coupled to the package substrate, at least two integrated circuit dies interconnected by the interconnect bridge circuitry die.

Example C10 includes the subject matter of Example C9, wherein the conductive materials comprise an intermetallic compound comprising copper and tin.

Example C11 includes the subject matter of Example C10, wherein the intermetallic compound comprises copper at between 60-75% by weight and tin at between 25-40% by weight.

Example C12 includes the subject matter of Example C10, wherein the intermetallic compound is a first intermetallic compound, and the conductive materials further comprise a second intermetallic compound comprising copper and tin.

Example C13 includes the subject matter of Example C12, wherein the second intermetallic compound comprises copper at between 50-70% by weight and tin at between 30-50% by weight.

Example C14 includes the subject matter of any one of Examples C9-C13, wherein the conductive materials do not include nickel.

Example C15 is a method of forming an integrated circuit package substrate comprising: forming buildup layers on a core layer, the buildup layers comprising a plurality of metallization layers; forming a cavity in the buildup layers to expose a subset of conductive contacts of a metallization layer; forming a first surface finish layer on the subset of conductive contacts, the first surface finish layer comprising gold; forming a second surface finish layer on the first surface finish layer, the second surface finish layer comprising palladium; forming a third surface finish layer on the second surface finish layer, the second surface finish layer comprising gold; placing a die within the cavity such that conductive contacts of the die are in electrical connection with the subset of conductive contacts.

Example C16 includes the subject matter of Example C15, wherein the first surface finish layer is formed using immersion plating, the second surface finish layer is formed using electroless plating, and the third surface finish layer is formed using immersion plating.

Example C17 includes the subject matter of Example C15 or C16, wherein the first surface finish layer is between 0.01-0.04 um thick, the second surface finish layer is between 0.02-0.15 um thick, and the third surface finish layer is between 0.03-0.10 um thick.

Example C18 includes the subject matter of Example C17, wherein the first surface finish layer is approximately 0.02 um thick, the second surface finish layer is approximately 0.10 um thick, and the third surface finish layer is approximately 0.08 um thick.

Example C19 includes the subject matter of any one of Examples C15-C18, wherein none of the first surface finish layer, the second finish layer, and the third surface finish layer include nickel.

Example C20 includes the subject matter of any one of Examples C15-C18, wherein the first surface finish layer is formed conformally around each conductive contact of the subset of conductive contacts.

Example D1 is an integrated circuit package substrate comprising: a plurality of metallization layers in dielectric buildup layers; a die within the buildup layers, the die comprising a conductive contact in electrical connection with a conductive contact of a metallization layer; and conductive materials between the conductive contact of the die and the conductive contact of the metallization layer, the conductive materials comprising indium and tin.

Example D2 includes the subject matter of Example D1, wherein the conductive materials comprise an intermetallic compound comprising indium and tin.

Example D3 includes the subject matter of Example D2, wherein the intermetallic compound comprises indium at between 1-5% by weight and tin at between 95-99% by weight.

Example D4 includes the subject matter of Example D2 or D3, wherein the conductive materials further comprise a layer comprising indium between the conductive contact of the metallization layer and the intermetallic compound.

Example D5 includes the subject matter of any one of Examples D1-D4, wherein the die is an interconnect bridge circuitry die.

Example D6 includes the subject matter of Example D5, wherein the interconnect bridge circuitry die comprises a through silicon via (TSV) connected to the conductive contact of the die.

Example D7 includes the subject matter of any one of Examples D1-D6, wherein the conductive materials are not conformally around the conductive contact of the metallization layer.

Example D8 includes the subject matter of any one of Examples D1-D7, wherein the conductive materials do not include nickel.

Example D9 is an integrated circuit package comprising: an integrated circuit package substrate comprising: a plurality of metallization layers in dielectric buildup layers; an interconnect bridge circuitry die embedded in the buildup layers, the interconnect bridge circuitry die comprising a via connected between a first conductive contact on a first side of the interconnect bridge circuitry die and a second conductive contact on a second side of the interconnect bridge circuitry die opposite the first side, the second conductive contact in electrical connection with a conductive contact of a metallization layer; and conductive materials between the second conductive contact of the interconnect bridge circuitry die and the conductive contact of the metallization layer, the conductive materials comprising indium and tin; and integrated circuit dies coupled to the package substrate, at least two integrated circuit dies interconnected by the interconnect bridge circuitry die.

Example D10 includes the subject matter of Example D9, wherein the conductive materials comprise an intermetallic compound comprising indium and tin.

Example D11 includes the subject matter of Example D10, wherein the intermetallic compound comprises indium at between 1-5% by weight and tin at between 95-99% by weight.

Example D12 includes the subject matter of Example D10 or D11, wherein the conductive materials further comprise a layer comprising indium between the conductive contact of the metallization layer and the intermetallic compound.

Example D13 includes the subject matter of any one of Examples D10-D12, wherein the conductive materials are not conformally around the conductive contact of the metallization layer.

Example D14 includes the subject matter of any one of Examples D10-D13, wherein the second conductive contact of the interconnect bridge circuitry die has a thickness greater than 12 um.

Example D15 includes the subject matter of any one of Examples D10-D14, wherein the conductive materials do not include nickel.

Example D16 is a method of forming an integrated circuit package substrate comprising: forming first buildup layers on a core layer, the first buildup layers comprising a plurality of metallization layers; forming a first surface finish layer on a subset of conductive contacts of a metallization layer of the first buildup layers, the first surface finish layer comprising indium; forming a second surface finish layer on the first surface finish layer, the second surface finish layer comprising palladium; forming a third surface finish layer on the second surface finish layer, the second surface finish layer comprising gold; forming second buildup layers on the first buildup layers; forming a cavity in the second buildup layers above the subset of conductive contacts; and placing a die within the cavity such that conductive contacts of the die are in electrical connection with the subset of conductive contacts.

Example D17 includes the subject matter of Example D16, wherein the first surface finish layer is formed via electrolytic plating, the second surface finish layer is formed via electrolytic plating, and the third surface finish layer is formed via electrolytic plating.

Example D18 includes the subject matter of Example D16 or D17, wherein the first surface finish layer is between 0.10-1 μm thick, the second surface finish layer is between 0.01-0.10 um thick, and the third surface finish layer is between 0.01-0.10 um thick.

Example D19 includes the subject matter of Example D18, wherein the first surface finish layer is approximately 1 um thick, the second surface finish layer is approximately 0.04 um thick, and the third surface finish layer is approximately 0.06 um thick.

Example D20 includes the subject matter of any one of Examples D16-D19, wherein the first surface finish layer is not formed conformally around each conductive contact of the subset of conductive contacts.

Example E1 is an integrated circuit package substrate comprising: a plurality of metallization layers in dielectric buildup layers; a die within the buildup layers, the die comprising a conductive contact in electrical connection with a conductive contact of a metallization layer; and conductive materials between the conductive contact of the die and the conductive contact of the metallization layer, the conductive materials comprising cobalt, iron, and tin.

Example E2 includes the subject matter of Example E1, wherein the conductive materials comprise an intermetallic compound comprising cobalt, iron, and tin.

Example E3 includes the subject matter of Example E2, wherein the intermetallic compound comprises cobalt at between 20-35% by weight, iron at between 10-30% by weight, and tin at between 65-85% by weight.

Example E4 includes the subject matter of Example E2 or E3, wherein the conductive materials further comprise a layer comprising cobalt and iron between the conductive contact of the metallization layer and the intermetallic compound.

Example E5 includes the subject matter of any one of Examples E1-E4, wherein the die is an interconnect bridge circuitry die.

Example E6 includes the subject matter of Example E5, wherein the interconnect bridge circuitry die comprises a through silicon via (TSV) connected to the conductive contact of the die.

Example E7 includes the subject matter of any one of Examples E1-E6, wherein the conductive materials are not conformally around the conductive contact of the metallization layer.

Example E8 includes the subject matter of any one of Examples E1-E7, wherein the conductive materials do not include nickel.

Example E9 is an integrated circuit package comprising: an integrated circuit package substrate comprising: a plurality of metallization layers in dielectric buildup layers; an interconnect bridge circuitry die embedded in the buildup layers, the interconnect bridge circuitry die comprising a via connected between a first conductive contact on a first side of the interconnect bridge circuitry die and a second conductive contact on a second side of the interconnect bridge circuitry die opposite the first side, the second conductive contact in electrical connection with a conductive contact of a metallization layer; and conductive materials between the second conductive contact of the interconnect bridge circuitry die and the conductive contact of the metallization layer, the conductive materials comprising cobalt, iron, and tin; and integrated circuit dies coupled to the package substrate, at least two integrated circuit dies interconnected by the interconnect bridge circuitry die.

Example E10 includes the subject matter of Example E9, wherein the conductive materials comprise an intermetallic compound comprising cobalt, iron, and tin.

Example E11 includes the subject matter of Example E10, wherein the intermetallic compound comprises cobalt at between 20-35% by weight, iron at between 10-30% by weight, and tin at between 65-85% by weight.

Example E12 includes the subject matter of Example E10 or E11, wherein the conductive materials further comprise a layer comprising cobalt and iron between the conductive contact of the metallization layer and the intermetallic compound.

Example E13 includes the subject matter of any one of Examples E10-E12, wherein the conductive materials are not conformally around the conductive contact of the metallization layer.

Example E14 includes the subject matter of any one of Examples E10-E13, wherein the second conductive contact of the interconnect bridge circuitry die has a thickness greater than 12 um.

Example E15 includes the subject matter of any one of Examples E10-E14, wherein the conductive materials do not include nickel.

Example E16 is a method of forming an integrated circuit package substrate comprising: forming first buildup layers on a core layer, the first buildup layers comprising a plurality of metallization layers; forming a first surface finish layer on a subset of conductive contacts of a metallization layer of the first buildup layers, the first surface finish layer comprising cobalt and iron; forming a second surface finish layer on the first surface finish layer, the second surface finish layer comprising palladium; forming a third surface finish layer on the second surface finish layer, the second surface finish layer comprising gold; forming second buildup layers on the first buildup layers; forming a cavity in the second buildup layers above the subset of conductive contacts; and placing a die within the cavity such that conductive contacts of the die are in electrical connection with the subset of conductive contacts.

Example E17 includes the subject matter of Example E16, wherein the first surface finish layer is formed via electrolytic plating, the second surface finish layer is formed via electrolytic plating, and the third surface finish layer is formed via electrolytic plating.

Example E18 includes the subject matter of Example E16 or E17, wherein the first surface finish layer is between 2-4 um thick, the second surface finish layer is between 0.01-0.10 um thick, and the third surface finish layer is between 0.01-0.10 um thick.

Example E19 includes the subject matter of Example E18, wherein the first surface finish layer is approximately 3.3 um thick, the second surface finish layer is approximately 0.04 um thick, and the third surface finish layer is approximately 0.06 um thick.

Example E20 includes the subject matter of any one of Examples E16-E19, wherein the first surface finish layer is not formed conformally around each conductive contact of the subset of conductive contacts.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit package substrate comprising:
a plurality of metallization layers in dielectric buildup layers;
a die within the buildup layers, the die comprising a conductive contact in electrical connection with a conductive contact of a metallization layer; and
conductive materials between the conductive contact of the die and the conductive contact of the metallization layer, the conductive materials comprising nickel, phosphorous, tin, and palladium.

2. The integrated circuit package substrate of claim 1, wherein the conductive materials comprise an intermetallic compound comprising nickel and phosphorous.

3. The integrated circuit package substrate of claim 2, wherein the intermetallic compound comprises phosphorous at between 15-30% by weight.

4. The integrated circuit package substrate of claim 1, wherein the conductive materials comprise an intermetallic compound comprising copper, nickel, tin, and palladium.

5. The integrated circuit package substrate of claim 4, wherein the intermetallic compound comprises copper at between 20-40% by weight, nickel at between 20-40% by weight, and tin at between 30-50% by weight.

6. The integrated circuit package substrate of claim 1, wherein the conductive materials comprise an intermetallic compound comprising nickel, tin, and phosphorous.

7. The integrated circuit package substrate of claim 1, wherein the conductive materials comprise a layer on the conductive pads of the metallization layer comprising nickel and phosphorous.

8. The integrated circuit package substrate of claim 1, wherein the die is an interconnect bridge circuitry die.

9. The integrated circuit package substrate of claim 8, wherein the interconnect bridge circuitry die comprises a through silicon via (TSV) connected to the conductive contact of the die.

10. The integrated circuit package substrate of claim 1, wherein the die is encapsulated in a cavity or opening in the buildup layers.

11. An integrated circuit package comprising:
an integrated circuit package substrate comprising:
a plurality of metallization layers in dielectric buildup layers;
an interconnect bridge circuitry die embedded in the buildup layers, the interconnect bridge circuitry die comprising a via connected between a first conductive contact on a first side of the interconnect bridge circuitry die and a second conductive contact on a second side of the interconnect bridge circuitry die opposite the first side, the second conductive contact in electrical connection with a conductive contact of a metallization layer; and
conductive materials between the second conductive contact of the interconnect bridge circuitry die and the conductive contact of the metallization layer, the conductive materials comprising nickel, phosphorous, tin, and palladium; and
integrated circuit dies coupled to the package substrate, at least two integrated circuit dies interconnected by the interconnect bridge circuitry die.

12. The integrated circuit package of claim 11, wherein the conductive materials comprise an intermetallic compound comprising nickel and phosphorous.

13. The integrated circuit package of claim 12, wherein the intermetallic compound comprises phosphorous at between 15-30% by weight.

14. The integrated circuit package of claim 11, wherein the conductive materials comprise an intermetallic compound comprising copper, nickel, tin, and palladium.

15. The integrated circuit package of claim 14, wherein the intermetallic compound comprises copper at between 20-40% by weight, nickel at between 20-40% by weight, and tin at between 30-50% by weight.

16. The integrated circuit package of claim 11, wherein the conductive materials comprise an intermetallic compound comprising nickel, tin, and phosphorous.

17. The integrated circuit package of claim 11, wherein the second conductive contact of the interconnect bridge circuitry die has a thickness between 5-12 um.

18. A method of forming an integrated circuit package substrate comprising:
forming buildup layers on a core layer, the buildup layers comprising a plurality of metallization layers;
forming a cavity in the buildup layers to expose a subset of conductive contacts of a metallization layer;
forming a first surface finish layer on the subset of conductive contacts, the first surface finish layer comprising nickel and having a thickness that is greater than 5 um;
forming a second surface finish layer on the first surface finish layer, the second surface finish layer comprising palladium;
forming a third surface finish layer on the second surface finish layer, the second surface finish layer comprising gold;
placing a die within the cavity such that conductive contacts of the die are in electrical connection with the subset of conductive contacts.

19. The method of claim 18, wherein the first surface finish layer is formed using electroless plating, the second surface finish layer is formed using electroless plating, and the third surface finish layer is formed using immersion plating.

20. The method of claim 18, wherein the first surface finish layer is between 5-10 um thick, the second surface finish layer is between 0.01-0.10 μm thick, and the third surface finish layer is between 0.01-0.10 μm thick.
